(19) United States
(12) Patent Application Publication
(10) Pub. No.: US 2021/0378143 A1
(43) Pub. Date: Dec. 2, 2021

(54) LIQUID DISTRIBUTION MODULE AND HEAT DISSIPATION SYSTEM

(71) Applicants: Lite-On Technology Corporation, Taipei (TW); Lite-On Singapore Pte Ltd, Singapore (SG)

(72) Inventors: Muhammad Azhar Abdul Gafar, Singapore (SG); Yijun Pan, Singapore (SG)

(73) Assignees: Lite-On Technology Corporation, Taipei (TW); Lite-On Singapore Pte Ltd, Singapore (SG)

(21) Appl. No.: 16/936,386

(22) Filed: Jul. 22, 2020

(30) Foreign Application Priority Data
May 29, 2020 (CN) 202010474561.0

(51) Int. Cl. H05K 7/20; F28F 27/02; F28F 3/12; F28F 13/08

(52) U.S. Cl. CPC H05K 7/20281; H05K 7/20254; F28F 13/08; F28F 3/12; F28F 27/02

(57) ABSTRACT

A liquid distribution module is configured to be connected to a cold plate. The liquid distribution module includes a main body, an inlet manifold, a flow control valve, and an outlet manifold. The inlet manifold is disposed on the main body and connected to the cooling liquid source. The inlet manifold includes a plurality of liquid inlets, wherein the plurality of liquid inlets are configured to connect a plurality of cold plate inlets of the cold plate respectively. The flow control valve is connected to the inlet manifold. The outlet manifold is disposed on the main body and includes a plurality of liquid outlets, wherein the plurality of liquid outlets are configured to connect a plurality of cold plate outlets of the cold plate respectively.

### CROSS-REFERENCE TO RELATED APPLICATION

This application claims the priority benefit of China patent application serial no. 202010474561.0, filed on May 29, 2020. The entirety of the above-mentioned patent application is hereby incorporated by reference herein and made a part of this specification.

### BACKGROUND

### Technical Field

The present disclosure generally relates to a liquid distribution module and a heat dissipation system using the same.

### Description of Related Art

At present, in a cold plate of an electronic device, the connection structures between the cold plate and the cooling liquid source are usually implemented through a plurality of tee tubes along with a plurality of hoses to connect to the interface of the cold plate and are locked and assembled through components such as screws, washers, and the like. However, the current liquid pipe connection structure has many complex components, so the disassembly and assembly thereof are relatively cumbersome. The more assembly components, the more difficult the consistency of assembly is, which results in loose connection between the connection structure and the cold plate or liquid leakage. Moreover, the overall size of the cold plate is rather large, which would occupy too much space in the electronic device.

In addition, in other conventional cold plate structures, the cold plate can be composed of base and cover, and liquid guiding grooves are formed directly on the base, and the cover is joined with the base by welding, so as to form liquid guiding channels in the cold plate for cooling liquid to flow through. However, the production cost of such cold plate (especially for larger cold plate) is relatively high, and the problem of leakage of cooling liquid is likely to occur.

### SUMMARY

Accordingly, the present disclosure is directed to a liquid distribution module and a heat dissipation system using the same, wherein the components of the liquid distribution module are more compact and simpler and can control the flow of the liquid inlet according to the temperature of the heat source.

The present disclosure provides a liquid distribution module configured to be connected to a cold plate. The liquid distribution module includes a main body, an inlet manifold, a flow control valve, and an outlet manifold. The inlet manifold is disposed on the main body and connected to the cooling liquid source. The inlet manifold includes a plurality of liquid inlets, wherein the plurality of liquid inlets are configured to connect a plurality of cold plate inlets of the cold plate respectively. The flow control valve is connected to the inlet manifold. The outlet manifold is disposed on the main body and includes a plurality of liquid outlets, wherein the plurality of liquid outlets are configured to connect a plurality of cold plate outlets of the cold plate respectively.

According to an embodiment of the present disclosure, the main body includes a liquid inlet portion and a liquid outlet portion. At least a part of the inlet manifold is embedded in the liquid inlet portion. The liquid inlet portion exposes the plurality of liquid inlet portions. At least a part of the outlet manifold is embedded in the liquid outlet portion, and the liquid outlet portion exposes the plurality of liquid outlets.

According to an embodiment of the present disclosure, the inlet manifold includes a main inlet pipe connected to the cooling liquid source and a plurality of sub inlet pipes connected to the main inlet pipe, and the plurality of liquid inlets are respectively disposed at the plurality of sub inlet pipes.

According to an embodiment of the present disclosure, the flow control valve is disposed on the main inlet pipe to control an amount of the cooling liquid flowing into the main inlet pipe.

According to an embodiment of the present disclosure, the flow control valve includes a plurality of flow control valves, which are respectively disposed on the plurality of sub inlet pipes to individually control an amount of the cooling liquid flowing into each of the plurality of sub inlet pipes.

According to an embodiment of the present disclosure, the liquid distribution module further includes a heat sensor coupled to the flow control valve, wherein degrees of openness and closeness of the flow control valve is responsive to heat source temperature sensed by the heat sensor.

According to an embodiment of the present disclosure, the flow control valve includes a solenoid valve.

The present disclosure provides a heat dissipation system includes a plurality of liquid distribution modules and cold plates. Each of the plurality of liquid distribution modules includes a main body, an inlet manifold connected to a cooling liquid source and an outlet manifold. The inlet manifold is disposed on the main body and includes a plurality of liquid inlets and a flow control valve disposed between the cooling liquid source and the plurality of liquid inlets. The outlet manifold is disposed on the main body and includes a plurality of liquid outlets, and the flow control valves of the plurality of liquid distribution modules individually control flow of the corresponding inlet manifolds of the plurality of liquid distribution modules. The cold plate is configured to contact the heat source and includes a plurality of cold plate inlets connected to the plurality of liquid inlets, a plurality of cold plate outlets connected to the plurality of liquid outlets, and a plurality of heat dissipation channels connected between the plurality of cold plate inlets and the plurality of cold plate outlets, wherein the plurality of heat dissipation channels respectively cross through the cold plate.

According to an embodiment of the present disclosure, each of the plurality of liquid distribution modules further includes a heat sensor coupled to the flow control valve, wherein the heat sensors of the plurality of liquid distribution modules are configured to generate a plurality of sensing signals according to a plurality of heat source temperature sensed by the heat sensors respectively.

According to an embodiment of the present disclosure, the heat dissipation system further includes a controller coupled to the plurality of liquid distribution modules to receive the plurality of sensing signals and individually control degrees of openness and closeness of the flow control valves of the plurality of liquid distribution modules accordingly.

In light of the foregoing, the liquid distribution module in the disclosure utilizes an inlet manifold and an outlet manifold fixed to the main body for distributing the cooling liquid, so as to achieve modularized design, thereby minimizing and simplifying the components of the liquid distribution module and reducing its overall volume. Moreover, the liquid distribution module of the embodiments includes a flow control valve disposed at the inlet manifold. The flow control valve can control the degrees of openness and closeness of the inlet manifold according to the temperature of the heat source, so as to perform different levels of heat dissipation upon multiple heat sources more efficiently, which in turn improves the heat dissipation performance and efficiency of the heat dissipation system using this liquid distribution module.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a schematic view of a liquid distribution module and a cold plate according to an embodiment of the present disclosure.

FIG. 1B is a schematic view of a cold plate according to another embodiment of the present disclosure.

FIG. 2 is a schematic front view of a liquid distribution module according to an embodiment of the disclosure.

FIG. 3 is a schematic cross-sectional view of the liquid distribution module of FIG. 2 along line A-A.

FIG. 4 is a schematic cross-sectional view of the liquid distribution module of FIG. 2 along line B-B.

FIG. 5 and FIG. 6 are schematic views of an operation scenario of a flow control valve according to an embodiment of the disclosure.

FIG. 7 is a schematic view of a heat dissipation system according to an embodiment of the disclosure.

FIG. 8 is a block diagram of a heat dissipation system according to an embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

The present disclosure will now be described more fully with reference to the accompanying drawings, in which exemplary embodiments of the disclosure are shown. The terms used herein such as “on”, “above”, “below”, “front”, “back”, “left” and “right” are for the purpose of describing directions in the figures only and are not intended to be limiting of the disclosure. Moreover, in the following embodiments, the same or similar reference numbers denote the same or like components.

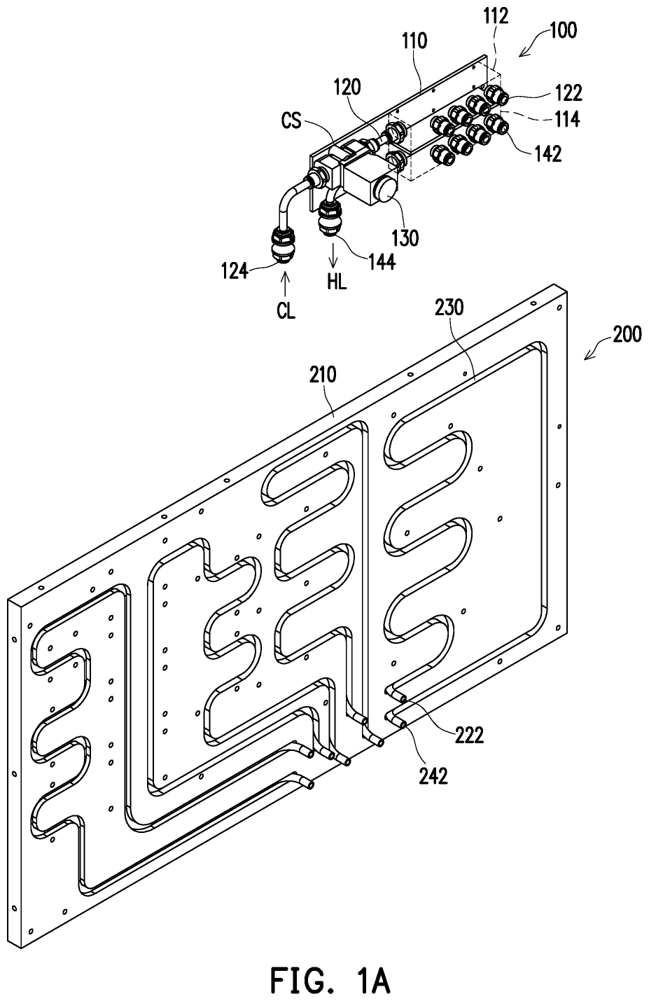

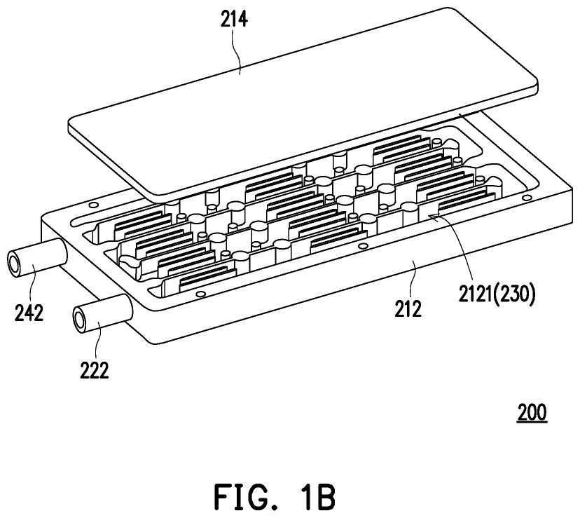

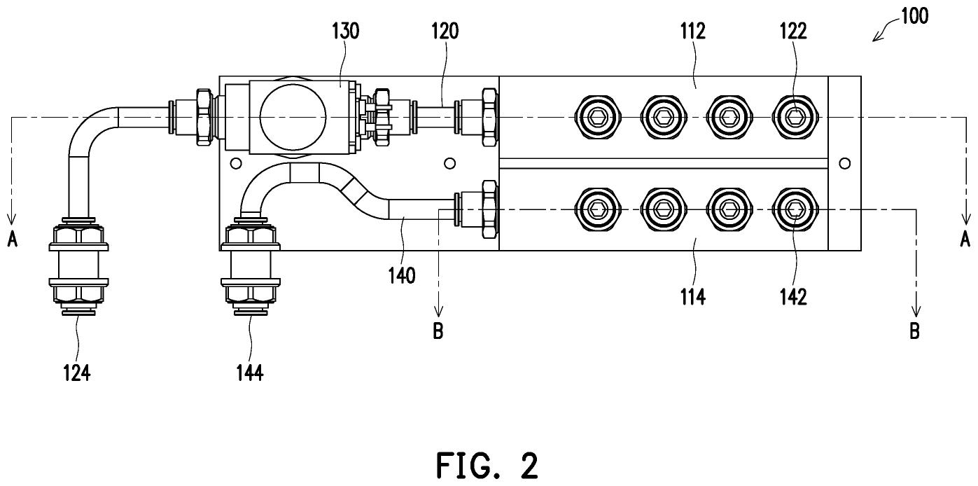

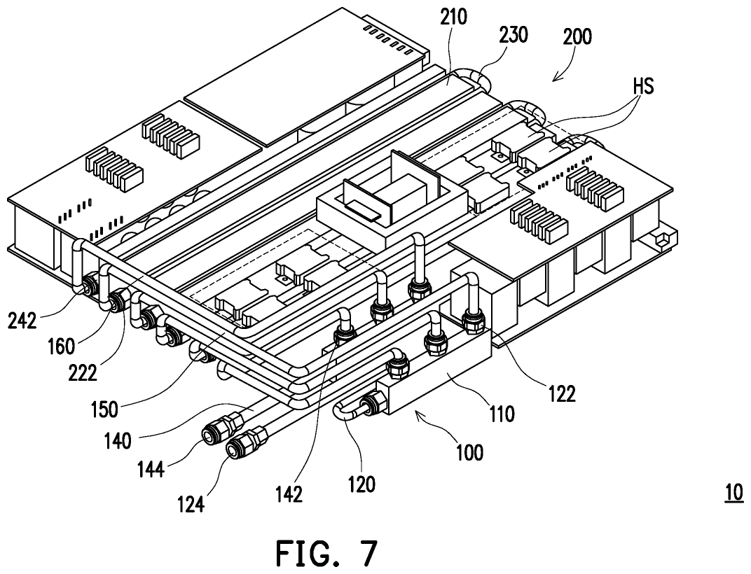

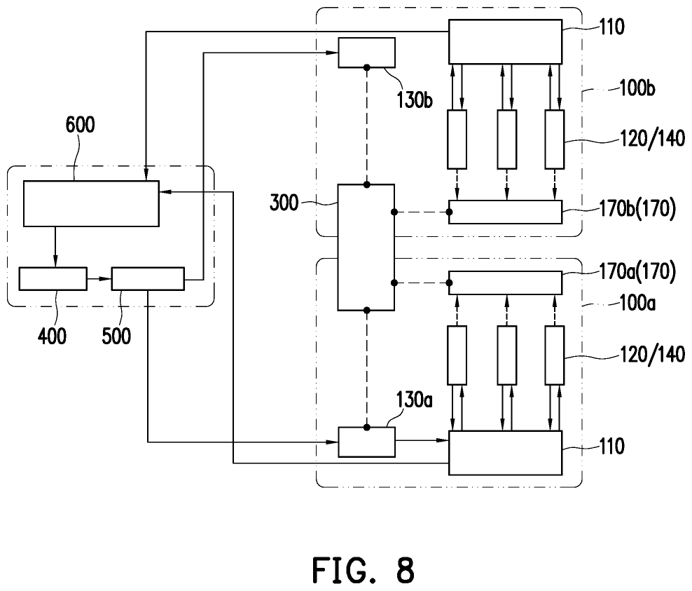

FIG. 1A is a schematic view of a liquid distribution module and a cold plate according to an embodiment of the present disclosure. FIG. 2 is a schematic front view of a liquid distribution module according to an embodiment of the disclosure. Referring to both FIG. 1A and FIG. 2, in some embodiments, the liquid distribution module 100 is configured to be connected to a cold plate 200 disposed on at least one heat source (such as, but not limited to, the heat source HS shown in FIG. 7), so that cooling liquid CL flows into and out of the cold plate 200 to perform heat dissipation to heat source HS. In some embodiments, the heat source HS may be, for example, a charger, a frequency converter, a photovoltaic inverter, a variable frequency motor driver, or any electronic device with a mass heat sources The heat source HS may be disposed on the cold plate 200, for example. In order to dissipate heat from interior of the heat source HS to exterior of the heat source HS. In some embodiments, cold plate 200 utilizes cooling liquid CL as a medium to exchange heat with heat source HS. For instance, the cooling liquid CL may include, for example, water, a mixture of water and ethylene glycol, oil, or other suitable cooling liquid. The common material of the plate body 210 of the cold plate 200 is aluminium alloy, copper, stainless steel, or other materials with high thermal conductivity. The liquid distribution module 100 is connected between the cold plate 200 and the cooling liquid source (such as but not limited to the cooling liquid source 400 shown in FIG. 8) to distribute the cooling liquid CL from the cooling liquid source 400 into the cold plate 200, and discharged the heat exchange liquid HL, that has been through heat exchange, out of cold plate 200.

FIG. 1B is a schematic view of a cold plate according to another embodiment of the present disclosure. It is noted that the cold plate 200 shown in FIG. 1B contains many features same as or similar to the cold plate 200 disclosed earlier with FIG. 1A. For purpose of clarity and simplicity, detail description of same or similar features may be omitted, and the same or similar reference numbers denote the same or like components. The main differences between the cold plate 200 shown in FIG. 1B and the cold plate 200 shown in FIG. 1A are described as follows.

Referring to FIG. 1B, in this embodiment, the cold plate 200 may include a base 212 and a cover 214. In some embodiments, the base 212 may include a plurality of liquid guiding grooves 2121, which may be formed directly (for example, by drilling or carving) On the base 212, and the liquid guiding groove 2121 can be evenly distributed in the base 212 and connected between the cold plate inlet 222 and the cold plate outlet 242. The cover 214 can be joined to the base 212 by welding, for example. In this way, the liquid guiding groove 2121 and the cover 214 of the base 212 can jointly form a plurality of heat dissipation channels 230 connected between the cold plate inlet 222 and the cold plate outlet 242. The heat dissipation channels 230 can respectively cross through the cold plate 200, which allows the entire cold Plate 200 to fully exchange heat with cooling liquid. Of course, the form of cold plate 200 is not limited thereto. In some embodiments, the liquid distribution module 100 may include, for example, a main body 110, an inlet manifold 120, a flow control valve 130, and an outlet manifold 140. Common materials for the main body 110 may include stainless steel, copper, aluminium alloy, plastic, or other suitable materials. In some embodiments, the main body 110 of the liquid distribution module 100 may be fixed on, for example, the housing CS of the electronic device. The inlet manifold 120 is disposed on the main body 110 and is connected to a cooling liquid source (such as but not limited to the cooling liquid source 400 shown in FIG. 8). In this embodiment, the inlet manifold 120 includes a plurality of liquid inlets 122 (shown as 4 liquid inlets 122 but not limited thereto) and an inlet end 124. Herein, the inlet end 124 is connected to the cooling liquid source, and the liquid inlet 122 is configured to be connected to a plurality of cold plate inlets 222 (illustrated as 4 cold plate inlets 222 but not limited thereto, and the quantity thereof should correspond to the quantity of the liquid inlet 122) of the cold plate 200. With such configuration, the cooling liquid CL from the cooling liquid source can flow into the inlet manifold 120 via the inlet end 124, and flow into the cold plate 200 via the liquid inlet 122 and the cold plate inlet 222.

Similarly, the outlet manifold 140 is disposed on the main body 110 and may include a plurality of liquid outlets 142 (shown as 4 liquid outlets 142 but not limited thereto) and an outlet end 144. Herein, the liquid outlet 142 is configured to connect a plurality of cold plate outlets 242 (illustrated as 4 cold plate outlets 242 but not limited thereto, and the quantity of the cold plate outlets 242 should correspond to that of the liquid outlets 142) of the cold plate 200. With such configuration, the heat exchange liquid HL after heat exchange in the cold plate 200 can flow out of the cold plate 200 through the cold plate outlets 242 and flow out of the liquid distribution module 100 through the liquid outlets 142 and outlet end 144 to complete the heat exchange.

In some embodiments, the flow control valve 130 may be disposed on the inlet manifold 120 and between the cooling liquid source (or the inlet end 124) and the plurality of liquid inlets 122. In detail, the main body 110 includes a liquid inlet portion 112 and a liquid outlet portion 114, which can respectively protrude from a main body surface of the main body 110. At least a part of the inlet manifold 120 is embedded in the liquid inlet portion 112, and the liquid inlet portion 112 exposes a plurality of liquid inlets 122 of the inlet manifold 120. Similarly, at least a part of the outlet manifold 140 is embedded in the liquid outlet portion 114, and the liquid outlet portion 114 exposes a plurality of liquid outlets of the outlet manifold 140. With such configuration, the liquid distribution module 100 of the present embodiment can jointly fix the inlet manifold 120, the flow control valve 130, and the outlet manifold 140 onto the main body 110 to achieve a modularized design. It is noted that, in other implementations, the flow control valve 130 may be connected to the inlet end 124 of the inlet manifold 120 first, so the cooling liquid CL may firstly flow into the flow control valve 130, and then flows to the liquid inlet 122 through the inlet end 124.

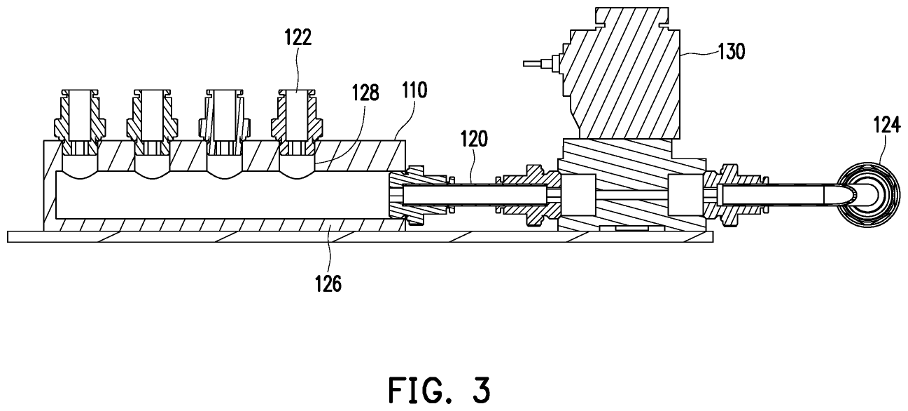

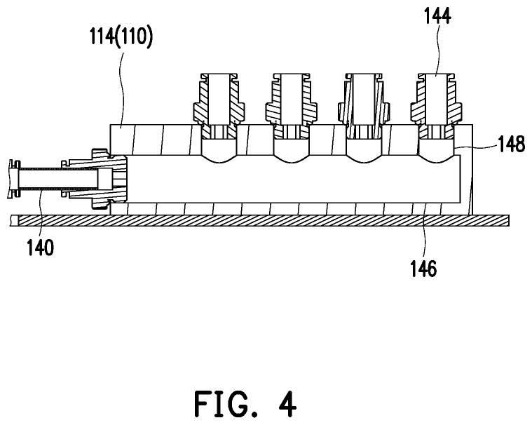

FIG. 3 is a schematic cross-sectional view of the liquid distribution module of FIG. 2 along line A-A. FIG. 4 is a schematic cross-sectional view of the liquid distribution module of FIG. 2 along line B-B. Referring to FIG. 3, in some embodiments, the inlet manifold 120 may include a main inlet pipe 126 and a plurality of sub inlet pipes 128. Herein, the main inlet pipe 126 is connected to the cooling liquid source (or inlet end 124), the sub inlet pipes 128 are respectively connected to the main inlet pipe 126, and the liquid inlets 122 are respectively located on the sub inlet pipes 128. Similarly, the outlet manifold 140 may include a main outlet pipe 146 and a plurality of sub-liquid pipes 148. Herein, the main outlet pipe 146 is connected to the outlet end 144, the sub-liquid pipes 148 are respectively connected to the main outlet pipe 146, and the liquid outlets 142 are respectively located on the sub-liquid pipes 148.

In the present embodiment, the flow control valve 130 may be disposed on the main inlet pipe 126 to control the amount of the cooling liquid CL flowing into the main inlet pipe 126.

In other embodiments, the quantity of the flow control valves 130 may be plural, which are respectively disposed on the plurality of sub inlet pipes 128 to individually control the amount of cooling liquid CL flowing into each of the sub inlet pipes 128.

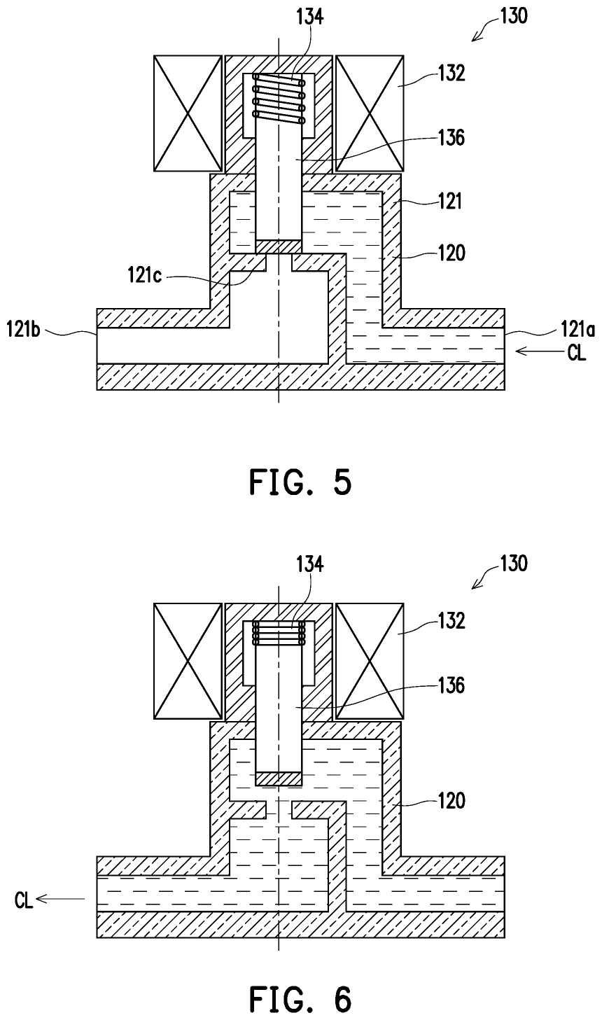

FIG. 5 and FIG. 6 are schematic views of an operation scenario of a flow control valve according to an embodiment of the disclosure. In some embodiments, the flow control valve 130 may be a solenoid valve. Specifically, the flow control valve 130 may include a coil 132, an elastic component 134, and a movable plunger 136. The inlet manifold 120 may have a valve base 121 engaged with the flow control valve 130. The valve base 121 has at least one inlet 121a and at least one outlet 121b. The valve base 121 is disposed among the flow path between the inlet 121a and the outlet 121b. The plunger 136 is engaged with the valve base 121, wherein the plunger 136 is movable, so as to open and close this flow control valve 130. The valve base 121 may include, for example, a stopper 121c that restrains the travel distance of the plunger 136. The elastic component 134 shifts the movable plunger 136 toward the stopper 121c until it reaches a closed position. In some embodiments, the elastic component 134 may be a coil spring, but may also be any other elements that is capable of applying force to the plunger 136 to shift it toward the stopper 121c. When the flow control valve 130 is in the closed state as shown in FIG. 5, the elastic (restoring) force of the elastic component 134 can push the plunger 136 toward the stopper 121c. Accordingly, in the closed position, the elastic component 134 pushes the movable plunger 136 to lean against the stopper 121c.

In some embodiments, the coil 132 is disposed around the plunger 136. The coil 132 is configured to move the plunger 136 away from the stopper 121c against the elastic force of the elastic component 134. When the coil 132 is conducted, the coil 132 makes the plunger 136 resist the restoring force of the elastic component 134, so that the plunger 136 can move away from the stopper 121c as shown in FIG. 6. As such, the flow control valve 130 is in an open state, and the cooling liquid CL can flow to the outlet 121b through the inlet 121a of the valve base 121. When the coil 132 is not conducted (power off), the elastic component 134 pushes the plunger 136 to the closed position until the plunger 136 contacts the stopper 121c, thereby blocking the flow path of the cooling liquid CL, so that the cooling liquid CL cannot flow to the outlet 121b through the inlet 121a of the valve base 121. The flow control valve 130 is thus closed. Certainly, the present embodiment is merely for illustration, and the flow control valve 130 may be any other suitable valve. The present embodiment is not limited thereto.

FIG. 7 is a schematic view of a heat dissipation system according to an embodiment of the disclosure. FIG. 8 is a block diagram of a heat dissipation system according to an embodiment of the disclosure. It should be noted that the liquid distribution module 100 and the cold plate 200 in FIG. 7 and FIG. 8 are substantially the same as or similar to the liquid distribution module 100 and the cold plate 200 in the foregoing embodiments, but the piping configuration in the liquid distribution module 100 and the cold plate in FIG. 7 and FIG. 8 is slightly different.

It should be noted that the liquid distribution module 100 and the cold plate 200 in FIG. 7 and FIG. 8 are substantially the same as or similar to the liquid distribution module 100 and the cold plate 200 in the foregoing embodiments, but the piping configuration in the liquid distribution module 100 and the cold plate in FIG. 7 and FIG. 8 is slightly different. Therefore, in this embodiment, some reference numbers and related contents of the foregoing embodiments are adopted. For purpose of clarity and simplicity, detail description of same or similar features may be omitted, and the same or similar reference numbers denote the same or like components.

Referring to both FIG. 7 and FIG. 8, in this embodiment, the liquid distribution module 100 may further include a heat sensor 170, which is coupled to the flow control valve 130. In some embodiments, the heat sensor 170 may be provided on the heat source HS. In other embodiments, the heat sensor 170 is disposed adjacent to the heat source HS. The present embodiment is not limited thereto, as long as the heat sensor 170 is configured close enough to be able to sense the temperature of the heat source HS. In some embodiments, the degrees of openness and closeness of the flow control valve 130 is in response to the heat source temperature sensed by the heat sensor 170. In other words, the openness and closeness of the flow control valve 130 or the degree of openness and closeness is determined according to the heat source temperature sensed by the heat sensor 170.

For example, when the temperature of the heat source sensed by the heat sensor 170 is greater than a preset value, the flow control valve 130 is opened to allow the cooling liquid CL to flow into the cold plate 200 from the liquid distribution module 100 for heat exchange. When the temperature of the heat source sensed by the heat sensor 170 is not greater than this preset value, the flow control valve 130 is closed to stop the cooling liquid CL from continuingly flowing into the cold plate 200. In the embodiment where the flow control valves 130 are respectively disposed on a plurality of liquid inlets 122 of the inlet manifold 120, the liquid distribution module 100 has a plurality of heat sensors 170, which are respectively disposed on a plurality of heat sources HS, or disposed on multiple regions of the same heat source. In this way, each of the flow control valves 130 can individually control the amount of the cooling liquid CL flowing through the corresponding liquid inlets 122 according to different heat source temperatures sensed by the heat sensors 170.

In other embodiments, the flow control valve 130 may be partially opened (or partially closed) to adjust the flow of the cooling liquid CL in more stages. In other words, the flow control valve 130 can adjust the degree of openness of the flow control valve 130 according to the temperature of the heat source sensed by the heat sensor 170. That is, the flow control valve 130 may be in different degree of openness as the temperature of the heat source rises and falls, so as to adjust the flow of cooling liquid CL. For example, when the temperature of the heat source sensed by the heat sensor 170 is greater than a first preset value, the flow control valve 130 is fully opened, so that huge amount of the cooling liquid CL flows into the cold plate 200 from the liquid distribution module 100 to perform heat exchange. When the temperature of the heat source sensed by the heat sensor 170 is substantially greater than a second preset value and less than or equal to the first preset value, the flow control valve 130 may be partially opened (or partially closed) to enable a fewer amount of the cooling liquid CL flows from the liquid distribution module 100 into the cold plate 200 for heat exchange. When the temperature of the heat source sensed by the heat sensor 170 is less than or equal to the second preset value, the flow control valve 130 is completely closed to stop the cooling liquid CL from continuingly flowing into the cold plate 200. Of course, the liquid distribution module 100 of the present embodiment can adjust the flow of the cooling liquid CL in even more stages according to actual requirements.

In some embodiments, the aforementioned liquid distribution module 100 may be applied to a heat dissipation system 10 to dissipate heat from the heat source HS. The heat dissipation system 10 may include one or more liquid distribution modules 100. FIG. 8 illustrates a block diagram of an embodiment in which the heat dissipation system 10 has a plurality of liquid distribution modules 100a and 100b (two liquid distribution modules are shown, but not limited thereto). However, the present embodiment does not limit the quantity of liquid distribution modules 100a, 100b. In the present embodiment, the cold plate 200 is configured to contact the heat source HS and includes a plurality of cold plate inlets 222, a plurality of cold plate outlets 242, and a plurality of heat dissipation channels 230 connected between the cold plate inlets 222 and the cold plate outlets 242. In some embodiments, a plurality of liquid inlets 122 may be connected to a plurality of cold plate inlets 222 via a plurality of first (flexible) hoses 150 respectively, and a plurality of liquid outlets 124 may be connected to a plurality of cold plate outlets 242 via a plurality of second (flexible) hoses 160 respectively. In addition, the heat dissipation channels 230 respectively cross through the plate body 210 of the cold plate 200, so that the entire plate body 210 can be fully in heat exchange with the cooling liquid CL.

In some embodiments, the heat dissipation system 10 may further include a controller 300, which is coupled to the liquid distribution modules 100a and 100b respectively. In detail, the controller 300 is coupled to the heat sensors 170a and 170b and the flow control valves 130a and 130b of the liquid distribution modules 100a and 100b. The heat sensors 170a and 170b can be respectively disposed on a plurality of heat sources HS or different regions of the same heat source HS. Accordingly, the heat sensors 170a and 170b may generate a plurality of sensing signals according to a plurality of heat source temperatures sensed by the heat sensors 170a and 170b. The controller 300 is configured to receive the plurality of sensing signals and individually control the openness and closeness or the degrees of openness and closeness of the flow control valves 130a and 130b accordingly. For example, when the temperature of the heat source sensed by the heat sensor 170a is higher than a preset value, and the temperature of the heat source sensed by the heat sensor 170b is lower than the preset value, the heat sensors 170a and 170b generate different sensing signals. The controller 300 receives two different sensing signals and controls the openness and closeness or the degrees of openness and closeness of the flow control valves 130a and 130b accordingly. For example, the flow control valve 130a is turned on (open), and the flow control valve 130b is turned off (close). With such configuration, the heat dissipation system 10 of the embodiments can individually control the openness or closeness of the liquid inlets 122 of the liquid distribution modules 100a and 100b according to different temperatures of the heat sources HS.

In addition, the heat exchange liquid HL that has been through heat exchange may flow back to the heat dissipation device 600 through the cold plate outlets 242 to cool down the heat exchange liquid HL. When the heat exchange liquid HL cools down to the temperature of the cooling liquid CL, it can flow back to the cooling liquid source 400, so that later on when heat dissipation is required, the cooling liquid CL can be pumped into the liquid distribution module 100 via, for example, the pump 500.

In summary, the liquid distribution module in the disclosure utilizes an inlet manifold and an outlet manifold fixed to the main body to distribute the cooling liquid, so as to achieve the modularized design, thereby simplifying the quantity of components of the liquid distribution module and reducing its overall size. Moreover, the liquid distribution module in the disclosure includes a flow control valve provided in the inlet manifold, which controls the openness or closeness of the inlet manifold according to the temperature of the heat source. Therefore, different levels (degrees) of heat dissipation can be performed on multiple heat sources more efficiently, thereby improving the heat dissipation performance and efficiency of the heat dissipation system using the liquid distribution module.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A liquid distribution module, configured to be connected to a cold plate, comprising:
a main body;
an inlet manifold disposed on the main body and connected to a cooling liquid source, wherein the inlet manifold comprises a plurality of liquid inlets configured to connect a plurality of cold plate inlets of the cold plate respectively;
a flow control valve connected to the inlet manifold; and
an outlet manifold disposed on the main body and comprising a plurality of liquid outlets, wherein the plurality of liquid outlets are configured to connect a plurality of cold plate outlets of the cold plate respectively.

2. The liquid distribution module as claimed in claim 1, wherein the main body comprises a liquid inlet portion and a liquid outlet portion, at least a part of the inlet manifold is embedded in the liquid inlet portion, the liquid inlet portion exposes the plurality of liquid inlet portions, at least a part of the outlet manifold is embedded in the liquid outlet portion, and the liquid outlet portion exposes the plurality of liquid outlets.

3. The liquid distribution module as claimed in claim 1, wherein the inlet manifold comprises a main inlet pipe connected to the cooling liquid source and a plurality of sub inlet pipes connected to the main inlet pipe, and the plurality of liquid inlets are respectively disposed at the plurality of sub inlet pipes.

4. The liquid distribution module as claimed in claim 3, wherein the flow control valve is disposed on the main inlet pipe to control an amount of a cooling liquid flowing into the main inlet pipe.

5. The liquid distribution module as claimed in claim 3, wherein the flow control valve comprises a plurality of flow control valves, which are respectively disposed on the plurality of sub inlet pipes to individually control an amount of a cooling liquid flowing into each of the plurality of sub inlet pipes.

6. The liquid distribution module as claimed in claim 1, further comprising a heat sensor coupled to the flow control valve, wherein degrees of openness and closeness of the flow control valve is in response to a heat source temperature sensed by the heat sensor.

7. The liquid distribution module as claimed in claim 1, wherein the flow control valve comprises a solenoid valve.

8. A heat dissipation system, comprising:
a plurality of liquid distribution modules, wherein each of the plurality of liquid distribution modules comprises a main body, an inlet manifold connected to a cooling liquid source and an outlet manifold, the inlet manifold is disposed on the main body and comprises a plurality of liquid inlets and a flow control valve disposed between the cooling liquid source and the plurality of liquid inlets, the outlet manifold is disposed on the main body and comprises a plurality of liquid outlets, and the flow control valves of the plurality of liquid distribution modules individually control flow of the corresponding inlet manifolds of the plurality of liquid distribution modules;
a cold plate configured to contact the heat source and comprises a plurality of cold plate inlets connected to the plurality of liquid inlets, a plurality of cold plate outlets connected to the plurality of liquid outlets, and a plurality of heat dissipation channels connected between the plurality of cold plate inlets and the plurality of cold plate outlets, wherein the plurality of heat dissipation channels respectively cross through the cold plate.

9. The liquid distribution module as claimed in claim 8, wherein each of the plurality of liquid distribution modules further comprises a heat sensor coupled to the flow control valve, wherein the heat sensors of the plurality of liquid distribution modules are configured to generate a plurality of sensing signals according to a plurality of heat source temperatures sensed by the heat sensors respectively.

10. The liquid distribution module as claimed in claim 8, further comprising a controller coupled to the plurality of liquid distribution modules to receive a plurality of sensing signals and individually control degrees of openness and closeness of the flow control valves of the plurality of liquid distribution modules accordingly.
